(19) United States
(12) Patent Application Publication
(10) Pub. No.: US 2014/0202385 A1
(43) Pub. Date: Jul. 24, 2014

(54) FLAT-PLATE TYPE PECVD DEVICE

(71) Applicant: SHENZHEN JT AUTOMATION EQUIPMENT CO., LTD., Shenzhen (CN)

(72) Inventor: Jiexin Chen, Shenzhen (CN)

(73) Assignee: Shenzhen JT Automation Equipment Co., Ltd., Shenzhen (CN)

(21) Appl. No.: 13/760,077

(22) Filed: Feb. 6, 2013

(30) Foreign Application Priority Data
Jan. 23, 2013 (CN) 201310024830.3

(51) Int. Cl. H01L 31/18

(52) U.S. Cl. CPC H01L 31/1876
USPC 118/723 I

(57) ABSTRACT

The present application discloses a flat-plate type PECVD device including a vacuum chamber for accommodating a work piece and a plasma emitter provided above the vacuum chamber. The plasma emitter includes an emitting box fixed to the vacuum chamber, and a radio frequency impedance matching device provided above the emitting box. A dielectric window is connected to a bottom portion of the emitting box, and an antenna body connected to the radio frequency impedance matching device is fixedly provided above the emitting box. The antenna body includes an antenna placed in the emitting box, and a connecting terminal for connecting the antenna and the radio frequency impedance matching device. A radio frequency power supply is externally connected to the radio frequency impedance matching device. A process gas intake pipe is fixedly provided on the vacuum chamber, and a mounting groove corresponding to the emitting box is provided above the vacuum chamber.

The present application claims the priority of Chinese Patent Application No. 201310024830.3, titled “FLAT-PLATE TYPE PECVD DEVICE”, filed with the Chinese State Intellectual Property Office on Jan. 23, 2013, the entire disclosure of which is incorporated herein by reference.

### FIELD OF THE INVENTION

The present application relates to the mechanical field, and more particular to a flat-plate type PECVD device.

### BACKGROUND OF THE INVENTION

In the prior art, in order to improve the efficiency of a silicon solar cell, firstly, it is required to passivate impurities and defects having electrical activity contained in the silicon material, so as to reduce the composite action on minority carrier caused by surface defects; secondly, it is required to reduce the reflection of the front surface of the solar cell, so as to increase absorption of sunlight by the cell.

On one hand, many dangling bonds exist on the silicon surface, and have strong attraction to a non-equilibrium carrier in an N-type emitting region such that composite action of the minority carrier may occur, thereby reducing current. Therefore, there is a need to use some atoms or molecules to make the dangling bonds on the surface saturated. As found by experiments, the SiNx film containing hydrogen has a strong passivation effect on the silicon surface, thereby reducing the unsaturated dangling bonds on the surface of the silicon material and lowering the surface level.

On the other hand, the refractive index of silicon is 3.8, if a smooth silicon surface is directly placed in the air with a refractive index of 1.0, the reflectance of light by the smooth silicon surface can achieve about 30%. The reflection can be partially reduced by texturing the surface, but it is still difficult to reduce the reflectance in large extent; particularly for polysilicon, it is corroded by isotropic acidic etching solution, if the amount is excessive, a leakage current of a PN junction will be affected, therefore the surface texturing does not has obvious effect on reducing reflection. Therefore, it is considered that a layer of transparent dielectric film with a moderated refractive index can be inserted between the silicon surface and the air so as to reduce the reflection on the surface. In industrial applications, because the refractive index of the SiNx film can vary from 1.9 to about 2.3 according to different values of x, and the SiNx film is more suitable to be used between the silicon with a refractive index of 3.8 and the air with a refractive index of 1.0 for reducing the reflection of visible light, thus the SiNx film is selected as the antireflection film for the silicon surface, and is also a relatively excellent antireflection film.

As described above, there are two effects for preparing SiNx film on the surface of the silicon, one of which is the surface passivation effect, and another one of which is reducing the reflection of the visible light by surface. In recent years, generally PECVD technology is used to prepare SiNx film, in which a low-temperature plasma is used as an energy source, a sample is placed on a cathode with glow discharge under low atmospheric pressure, then the sample is heated to a predetermined temperature by the glow discharge (or by an additional heating element). Then an appropriate amount of reactive gas is fed in, after a series of chemical reactions and plasma reactions of the gas, a solid thin film is formed on the sample surface. The PECVD technology has advantages of low temperature, high efficiency-cost ratio and etc., and can complete passivation and antireflection film deposition at one time, thereby effectively reducing the composite rate and the reflectance of the surface of the silicon material, and ultimately improving the efficiency of the cell.

The main standard for evaluating the PECVD technology is depended on that whether a high-efficiency and high-quality deposition of silicon nitride film can be achieved, therefore, extensive researches are carried out to achieve this standard.

Existing PECVD technology mainly includes flat-plate type and tube-type, the conventional flat-plate type PECVD technology includes a direct method and a microwave indirect method. As shown in FIGS. 1 and 2, structural schematic views of two kinds of conventional flat-plate type PECVD device are shown.

Referring to FIG. 1 firstly, the flat-plate type PECVD device in direct method includes a sample holder 1, a deposition chamber 2 and a flat-plate electrode 3. The working process of the flat-plate type PECVD device is as follows, a plurality of cell pieces are placed on a holder 1 made from graphite or carbon fiber, and then the holder 1 is placed into the metallic deposition chamber 2, the flat-plate type electrode 3 is located in the chamber, and a discharge circuit is formed between the electrode 3 and the sample holder 1. Under the action of AC electric field between two electrode plates, the process gas 4 in the chamber forms plasma 5 in the space, SiNx containing hydrogen is formed by dissociating Si and H from the SiH4 and N and H from the NH3 which, and then is deposited onto the surface of a sample 6, wherein an outlet 7 is connected to a vacuum suction pump such that the chamber maintains vacuum state in the whole process.

Secondly, in the microwave indirect method, the sample to be deposited is placed outside the plasma region, and the plasma is directly hit on the surface of the sample, and the sample or the holder thereof is not a part of the electrode. Referring to FIG. 2, the structure of the microwave indirect method mainly includes a microwave source 8 with a frequency of 2.45 GHz, a copper antenna 9, a quartz tube 10, a magnetic pole 11, a holding plate 12 and a vacuum chamber 2. The copper antenna 9 is placed inside the quartz tube 10, the microwave source 8 is placed at two ends of the copper antenna 9 outside the sample region. Process gas of silane (SiH4) and ammonia gas (NH3) are respectively blown from the top of the chamber, the ammonia gas is ionized around the quartz tube to generate plasma 5, and then the silane gas is bombarded, thereby generating SiNx molecules, then under the guiding of the magnetic field SiNx molecules are deposited onto the surface of the sample 6.

Although the two conventional PECVD technologies can achieve deposition technology for depositing the SiNx thin film, there are many disadvantages as follows.

1. After the metal electrode of the flat-plate type PECVD device in direct method works in a high temperature environment for a long time, the electrode plate will be deformed, thereby a distance between the two electrode plates will change, which may cause the deposited film being not uniform.

2. The electrode of the flat-plate type PECVD device in direct method is located right above the sample and directly contacts plasma, such that the plasma is easy to be attached onto the electrode surface, and after a long period of use, dust will be accumulated and then fallen off to contaminate the sample. If there are impurities on the surface of the cell piece, the conversion efficiency of the cell will be reduced, and the cell may even be scrapped.

3. The flat-plate type PECVD device in direct method generally uses medium/low-frequency power supply (ranged from 40 to 460 kHz), the film quality is relatively dense, but great damage to the surface of the substrate may be caused by the overly high ion energy.

4. The frequency of microwave source of the microwave indirect PECVD device is 2.45 GHz, and the energy of the plasma generated by the microwave effect is low, thus affecting film quality.

5. In the microwave indirect PECVD device, in order to protect the microwave transmitting antenna from being eroded by plasma, the quartz tube is used outside the antenna for protection. But the quartz tube is exposed to the plasma environment for a long period of time, the surface thereof will be attached with a large amount of dust; in order to ensure the function of the quartz tub, there is a need to change the quartz tube frequently, thereby not only increasing the maintenance costs for the customer, but also shortening the maintenance interval.

6. In the microwave indirect PECVD device, the plasma is not formed above the sample, but is guided by magnetic field and gas flow to be at the top of the work piece, and then is deposited on the surface of the sample. The film formed in this way is loose and has a poor quality.

### SUMMARY OF THE INVENTION

In order to overcome the defects in the prior art, an object of embodiments of the present application is to provide a flat-plate type PECVD device, which is particularly suitable for surface deposition of cell piece film such as silicon nitride, silicon oxide.

In order to achieve the above object, embodiments of the present application provide the following technical solutions.

A flat-plate type PECVD device includes a vacuum chamber for accommodating a work piece and a plasma emitter provided above the vacuum chamber, wherein the plasma emitter includes an emitting box fixed to the vacuum chamber, and a radio frequency impedance matching device provided above the emitting box; a dielectric window is connected to a bottom portion of the emitting box, and an antenna body connected to the radio frequency impedance matching device is fixedly provided above the emitting box; the antenna body includes an antenna placed in the emitting box, and a connecting terminal for connecting the antenna and the radio frequency impedance matching device; a radio frequency power supply is externally connected to the radio frequency impedance matching device; and a process gas intake pipe is fixedly provided on the vacuum chamber, and a mounting groove corresponding to the emitting box is provided above the vacuum chamber.

As a further technical solution, the flat-plate type PECVD device further includes a work piece holder for holding the work piece, wherein the vacuum chamber is of a cuboid shape; two opposite end faces of the vacuum chamber are respectively provided with an inlet slot and an outlet slot for the work piece; and a vacuum valve is provided at a side face of the vacuum chamber.

As a further technical solution, a support roller for supporting the work piece holder is provided in the vacuum chamber.

As a further technical solution, the process gas intake pipe is located below the dielectric window; the dielectric window is a quartz dielectric window; and the antenna includes two butterfly-type copper antennas.

As a further technical solution, the flat-plate type PECVD device further includes a mounting box for accommodating the radio frequency impedance matching device; wherein the connecting terminal is a porcelain through terminal, and a frequency of the radio frequency power supply is ranged from 1 MHz to 300 MHz.

As a further technical solution, the support roller is a sealed driving wheel fixedly provided on a side wall of the vacuum chamber, each of two opposite side walls of the vacuum chamber is provided with two to six sealed driving wheels; and an end of each of the sealed driving wheels extends to an outside of the vacuum chamber and is drivably connected to a drive mechanism.

As a further technical solution, a sealing baffle is provided outside both the inlet slot and the outlet slot; the process gas intake pipe is a frame-shaped pipe connected with one intake branch pipe; and several gas outlet holes, gas outlet directions of which are parallel to a lower end face of the quartz dielectric window, are evenly provided at an outer side of the frame-shaped pipe.

As a further technical solution, the vacuum chamber is provided, at both an inlet side and an outlet side of the work piece holder, with connecting holes for realizing sealing connection; and there are more than two vacuum chambers.

As a further technical solution, the vacuum valve is provided with a vacuum valve motor; an intake valve is further provided at the inlet end of the process gas intake pipe; and the PECVD device further includes a controller electrically connected to the radio frequency power supply, the vacuum valve motor, the intake valve and the drive mechanism.

As a further technical solution, there are two plasma emitters, two radio frequency impedance matching devices, and two mounting grooves.

As can be seen from the above technical solutions, compared to the prior art, the embodiments of the application have the following beneficial effects.

The present application employs a radio frequency power supply having a RF frequency ranged from 1 MHz to 300 MHz, which reduces harm to human body. Meanwhile, since the energy of the plasma is mainly determined by the frequency of the power source, the lower the frequency is, the higher the bombarding energy of the plasma is. Compared to the microwave source (GHz), the plasma generated by the RF frequency (MHz) has a higher energy, thus the deposited product such as a silicon nitride film is denser. The PECVD in direct method generally employs a medium/low frequency power (ranged from 40 KHz to 460 KHz), although the film quality is denser, great damage to the surface of the substrate may be caused by the overly high ion energy.

Hence, the present application employs a high power radio frequency power supply and combines an automatic matching network, such that the transmission efficiency of the energy is greatly increased and the radio frequency power may be efficiently transmitted to the plasma. The copper antenna of the present application has a unique butterfly-type shape, and when designing the antenna, the function of directional transmission is emphasized, thus the direction of the plasma is fully controlled by the antenna, thus there is no need to provide an additional magnetic field. Therefore, the present application may efficiently generate a large area of plasma having a high density and being uniform. The plasma and the antenna are separated by the quartz dielectric window employed in the present application, which prevents the antenna from contacting the plasma, thereby avoiding the antenna being eroded, and there is no need to frequently change the quartz tube for protecting the antenna, which reduces many maintenance costs. The present application employs a unique process gas feeding manner, that is the reactive gas is blown to the bottom of the quartz dielectric window from the side face of the lower portion of the electrical dielectric window (i.e. the quartz dielectric window), such that the concentration of the plasma which are adjacent to the electrical dielectric window is greatly decreased and the adhesion of the plasma to the quartz dielectric window is reduced, therefore, the situation that the plasma are gathered and fallen onto the surface of the sample after a long time operation is not easy to happen, which improves the cleanliness of the cell piece (i.e. the work piece). Meanwhile, in design, the even distribution of the gas inlets is emphasized and blind spots of gas distribution are eliminated, such that the gas in the reactive surface of the substrate is more even. The combined operation between the PECVD device in the present application, the feeding mechanism (for automatic feeding the work piece holder), the removing mechanism (for automatic removing the work piece holder) and other devices can be realized via the controller, such that an automatic production line is formed. In short, the present application has a radio frequency power supply which is stable, safe and has a moderate energy, a copper antenna which controls the plasma, and a unique process gas feeding manner, thus work piece deposited by the present application, such as a silicon nitride film or a silicon oxide film, may have excellent performances, for example, uniformity, compactness and pollution-free.

### BRIEF DESCRIPTION OF THE DRAWINGS

FIG. 1 is a structural schematic view of a flat-plate type PECVD device in direct method in the prior art;

FIG. 2 is a structural schematic view of a flat-plate type PECVD device in indirect method in the prior art;

FIG. 3 is a perspective view of a flat-plate type PECVD device according to embodiments of the present application (in the Figure, one end face of a vacuum chamber is not closed and is provided to connect to another adjacent vacuum chamber so as to form an embodiment with two vacuum chambers and four emitters);

FIG. 4 is an exploded perspective view of a flat-plate type PECVD device according to a first embodiment of the present application;

FIG. 5A is another exploded perspective view of the flat-plate type PECVD device according to the first embodiment of the present application;

FIG. 5B is a perspective view of a process gas intake pipe of the flat-plate type PECVD device according to the first embodiment of the present application;

FIG. 5C is a perspective view of an antenna in the flat-plate type PECVD device according to the first embodiment of the present application;

FIG. 6 is a front view of the flat-plate type PECVD device according to the first embodiment of the present application;

FIG. 7 is a top view of the flat-plate type PECVD device according to the first embodiment of the present application;

FIG. 8 is a front structural schematic view of a flat-plate type PECVD device according to a second embodiment of the present application;

FIG. 9 is a front structural schematic view of a flat-plate type PECVD device according to a third embodiment of the present application;

FIG. 10 is a block schematic diagram of a control part of the flat-plate type PECVD device according to the first embodiment of the present application.

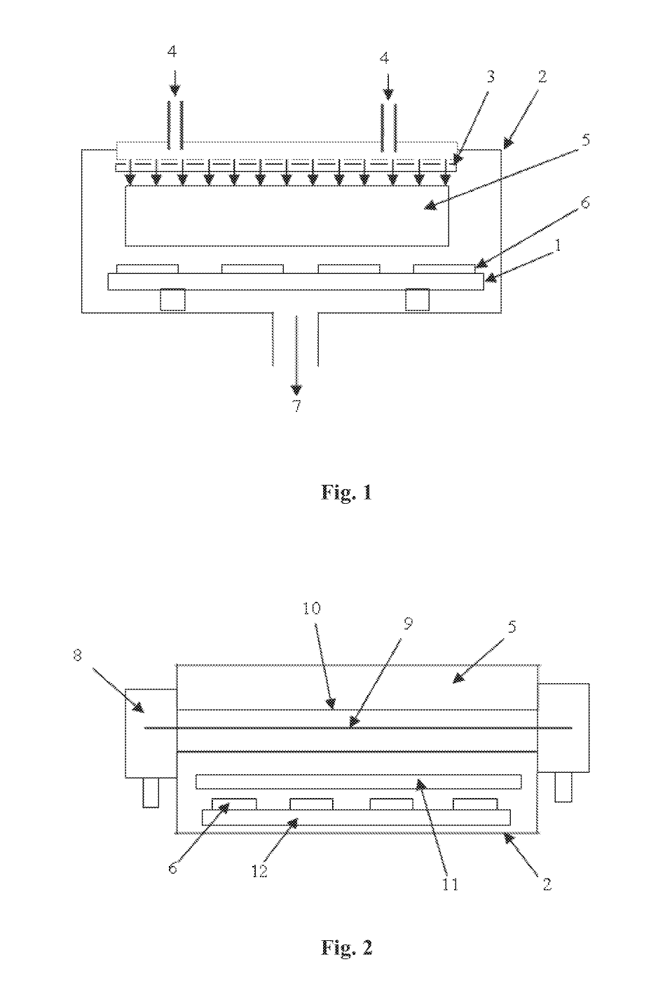

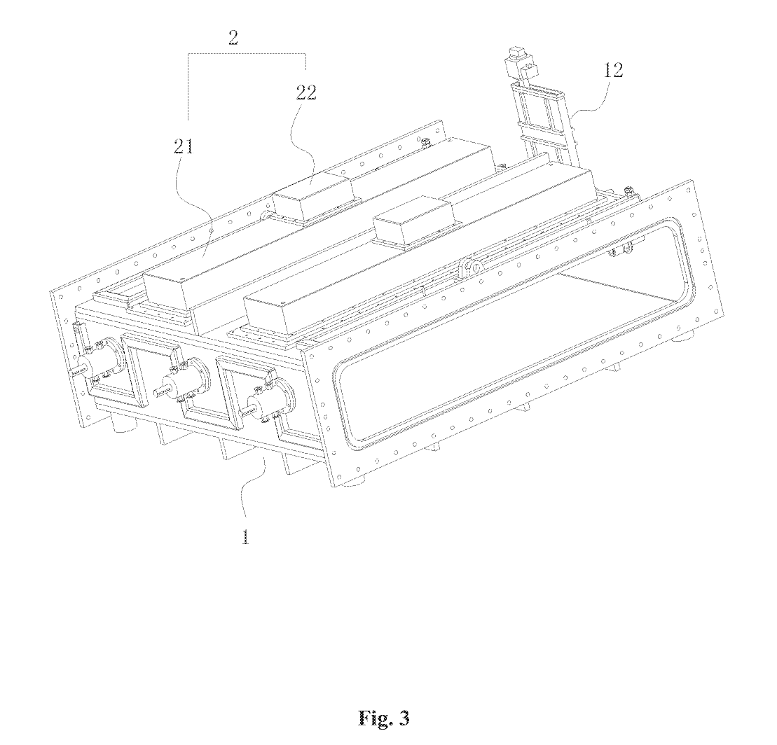

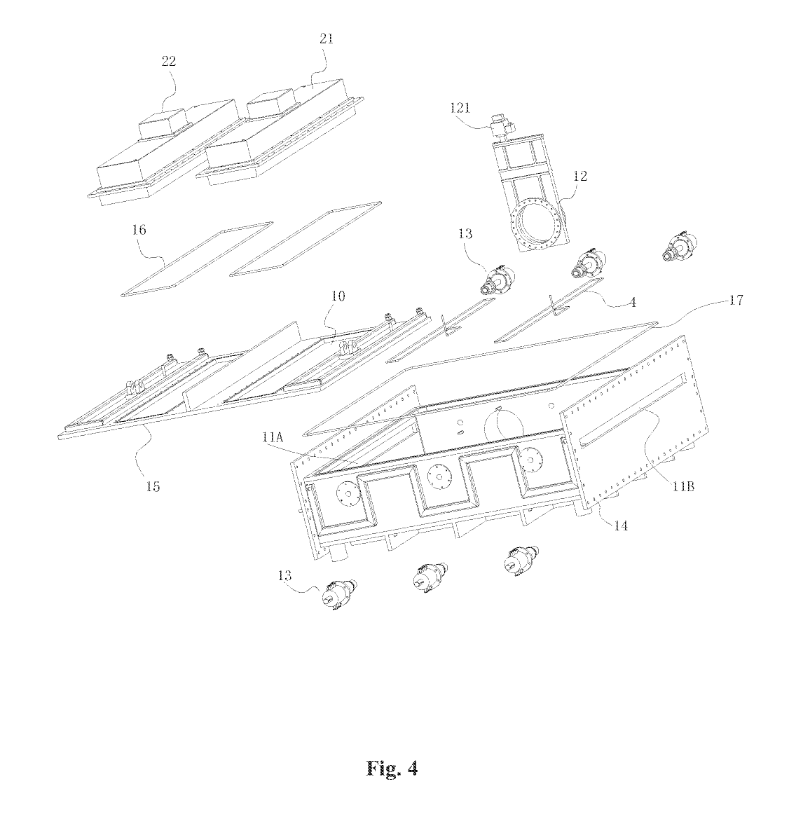

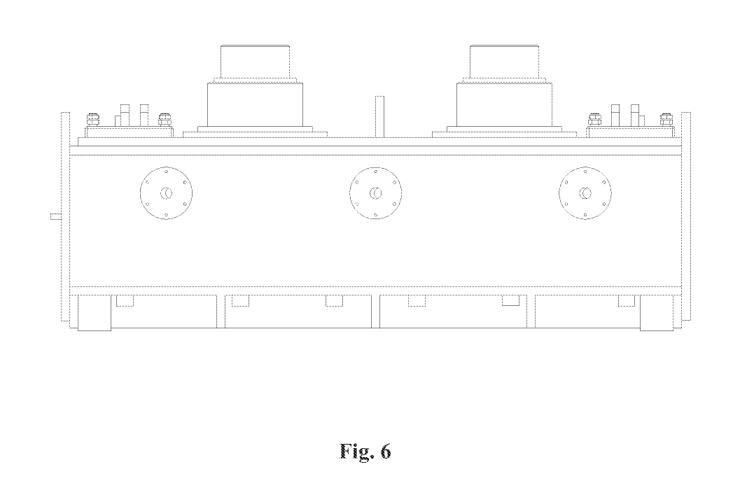

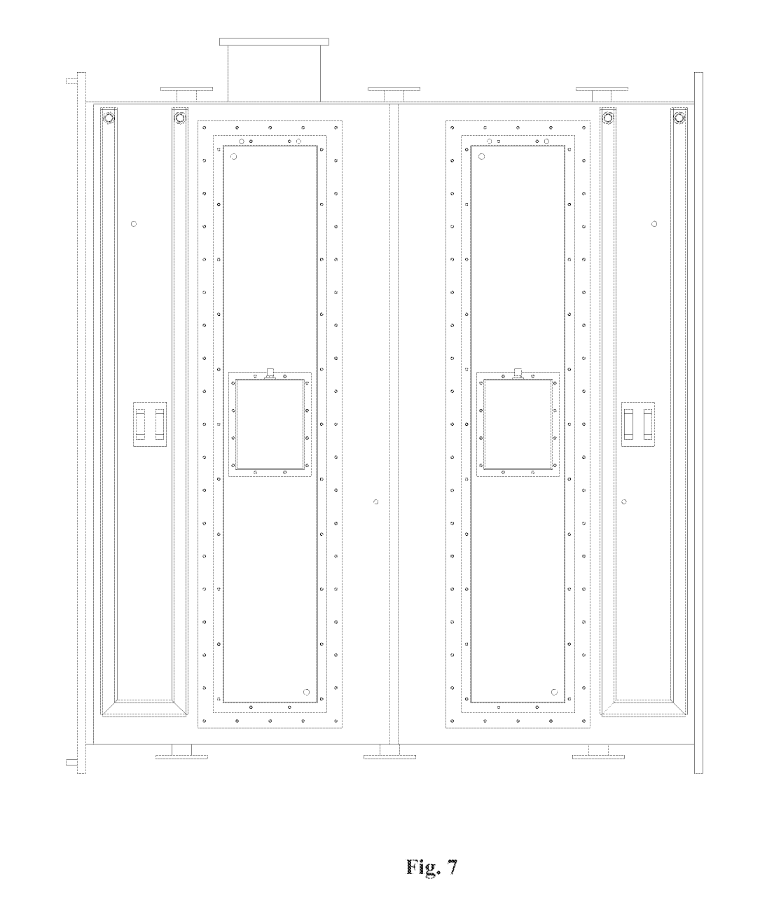

Reference numerals in FIGS. 3 to 10:

| 1 | vacuum chamber, | 10 | mounting groove, |
|---|---|---|---|
| 11A | inlet slot, | 11B | outlet slot, |
| 12 | vacuum valve, | 121 | vacuum valve motor, |
| 13 | support roller, | 131 | drive mechanism, |
| 14 | connecting hole, | 15 | top cover, |
| 16 | sealing ring, | 17 | sealing ring, |
| 2 | plasma emitter, | 21 | emitting box, |
| 211 | connecting body, | | |
| 22 | radio frequency impedance matching device, | | |
| 23 | antenna body, | 231 | antenna, |
| 232 | connecting terminal, | 3 | dielectric window, |
| 31 | sealing ring, | 4 | process gas intake pipe, |
| 41 | intake branch pipe, | 42 | frame-shaped pipe, |
| 43 | intake valve, | 44 | pipe clamp, |
| 5 | work piece holder, | 51 | work piece, |
| 8 | controller, and | 81 | radio frequency power supply. |

### DETAILED DESCRIPTION OF THE INVENTION

For better understanding the technical content of the present application, the technical solutions of the present application will be described hereinafter in conjunction with specific embodiments, but the technical solutions of the present application are not limited to these embodiments.

As shown in FIGS. 3 to 7, a flat-plate type PECVD device according to a first embodiment of the present application (using the structure of single vacuum chamber), includes a vacuum chamber 1 for accommodating a work piece (i.e. a target object needed to be performed with a PECVD deposition, in the present embodiment the work piece refers to a thin film used on a surface of the solar cell), and a plasma emitter 2 provided above the vacuum chamber 1. The plasma emitter 2 includes an emitting box 21 fixed to the vacuum chamber 1, and a radio frequency impedance matching device 22 provided above the emitting box 21. A dielectric window 3 (may also be referred to as an electrical dielectric window) is connected to a bottom portion of the emitting box 21, and a sealing ring 31 is provided at an upper side of the dielectric window 3 for realizing a sealing connection. In order to facilitate the installation and fixation of the dielectric window 3, a connecting body 221 is further provided below the emitting box 21 (a sealing ring 16 is provided between the connecting body 211 and a top cover 15). An antenna body 23 connected to the radio frequency impedance matching device 22 is fixedly provided above the emitting box 21, the antenna body 23 includes an antenna 231 placed in the emitting box 21, and a connecting terminal 232 for connecting the antenna 231 and the radio frequency impedance matching device 22. A radio frequency power supply (an independent purchased device) is externally connected to the radio frequency impedance matching device 22. A process gas intake pipe 4 is fixedly provided on the vacuum chamber 1, and a mounting groove 10 corresponding to the emitting box 21 is provided above the vacuum chamber 1. The vacuum chamber 1 adopts a separated type structure, a top portion thereof is a separated type top cover 15 (which is sealingly connected via a sealing ring 17), and the mounting groove 10 is provided on the top cover 15. The flat-plate type PECVD device further includes a work piece holder 5 for holding the work piece 51. The vacuum chamber 1 is of a cuboid shape, two opposite end faces of the vacuum chamber 1 are respectively provided with an inlet slot 11A and an outlet slot 11B for pushing in and taking out the work piece holder 5, and a vacuum valve 12 is provided at a side face of the vacuum chamber 1. A support roller 13 for supporting the work piece holder 5 is provided in the vacuum chamber 1. The process gas intake pipe 4 is located below the dielectric window 3; the dielectric window 3 is a quartz dielectric window; and the antenna 231 includes two butterfly-type copper antennas. The flat-plate type PECVD device further includes a mounting box (not shown separately in Figures) for accommodating the radio frequency impedance matching device 22. The connecting terminal 232 is a porcelain through terminal, and a frequency of the radio frequency power supply is ranged from 1 MHz to 300 MHz. The support roller 13 is a sealed driving wheel fixedly provided on a side wall of the vacuum chamber 1, each of two opposite side walls of the vacuum chamber is provided with two to six sealed driving wheels, and an end of each of the sealed driving wheels extends to an outside of the vacuum chamber 1 and is drivably connected to a drive mechanism 131. In the present embodiment, the support roller 13 adopts an integrated structure having a drive motor or a pneumatic motor.

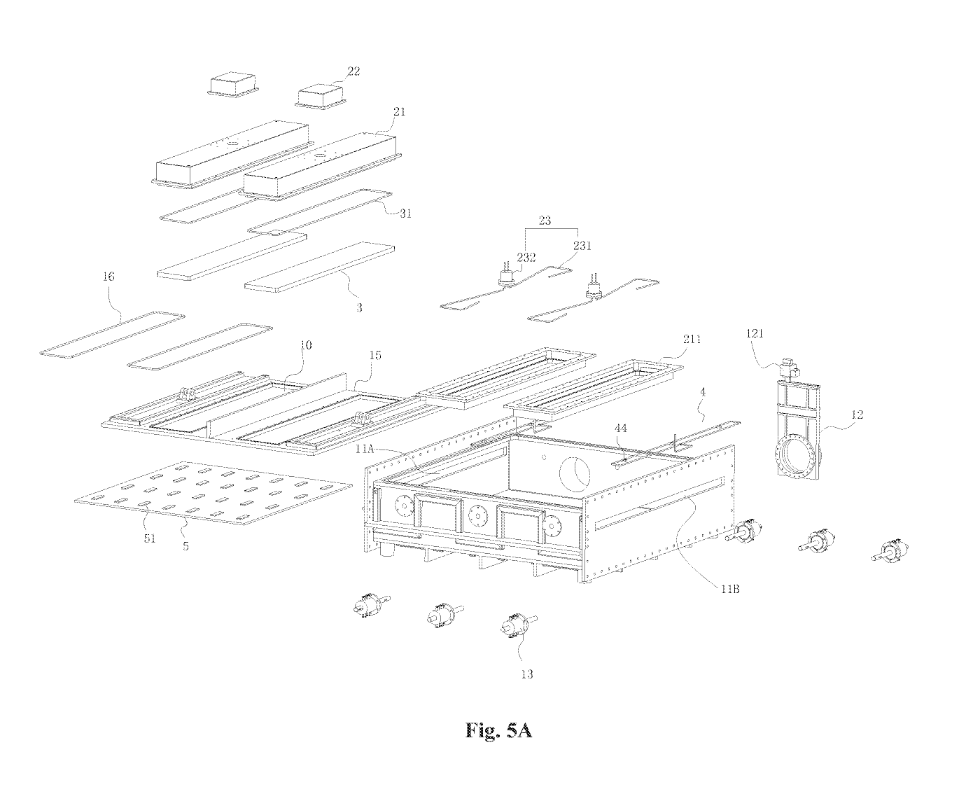

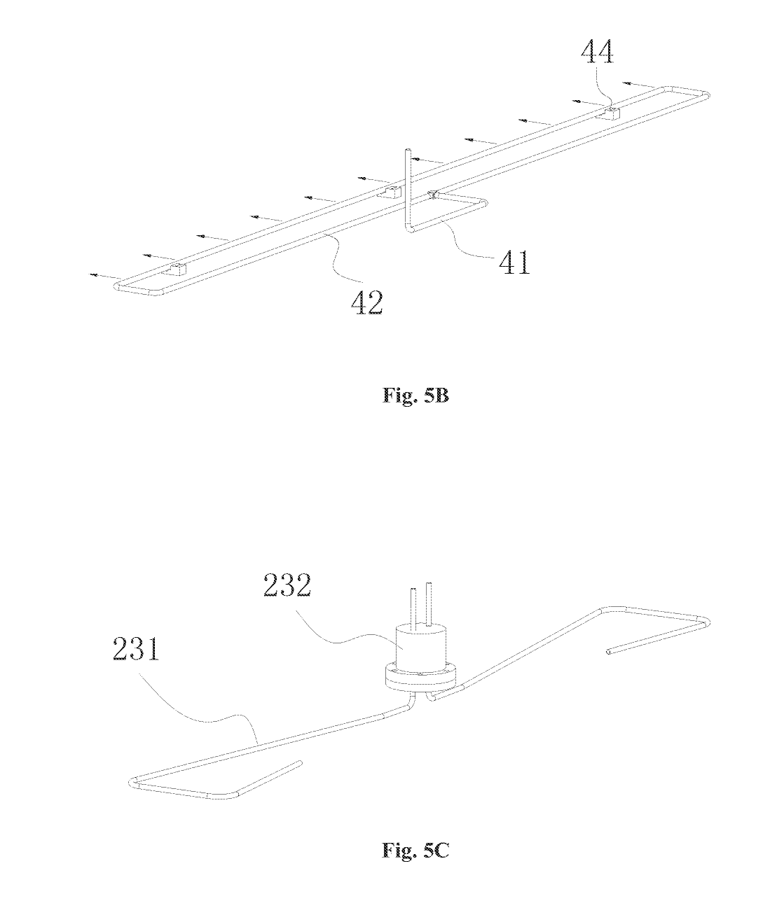

A sealing baffle (not shown in the Figures, the sealing baffle can be automatically opened or closed via a linkage mechanism) is provided outside both the inlet slot 11A and the outlet slot 11B. The process gas intake pipe 4 is a frame-shaped pipe 42 connected with one intake branch pipe 41, and several gas outlet holes, gas outlet directions (as shown by arrows in FIG. 5B) of which are parallel to a lower end face of the quartz dielectric window, are evenly provided at an outer side of the frame-shaped pipe 42. The process gas intake pipe 4 is fixed to the vacuum chamber 1 via a pipe clamp 44. The vacuum chamber 1 is provided, at both an inlet side and an outlet side of the work piece holder 5, with connecting holes 14 for realizing sealing connection, such that a plurality of vacuum chambers can be connected together.

In the above structure, when designing the structure of the antenna, the function of directional transmission is emphasized, thus the direction and scope of the plasma can be effectively controlled, and there is no need to provide an additional magnetic field, thereby reducing the technology process. The quartz dielectric window has the function of protecting the copper antenna from being eroded by plasma. The process gas intake pipe has a unique gas outlet manner, that is the reaction gas is blown to the bottom of the quartz dielectric window from a side face of a lower portion of the dielectric window, thereby not only reducing the contact between the plasma and the dielectric window, but also ensuring the gas in the vacuum chamber being distributed uniformly and ensuring the deposited film being clean and uniform.

The working process of the present application is as follows. Firstly, the vacuum chamber is pumped to be in a vacuum state by the vacuum valve, then the vacuum valve is closed, and the process gas is input via the process gas intake pipe under the vacuum state. The radio frequency power supply is started after the flow of the process gas is stable, then radio frequency waves emitted by the copper antenna is transmitted into the vacuum chamber via the quartz dielectric window to excite the process gas into plasma, and then under the control of the antenna, the plasma will be evenly deposited on a surface of the work piece (a cell piece).

In a more specific technical content, the vacuum valve 12 is provided with a vacuum valve motor 121, and an intake valve 43 is further provided at an inlet end of the process gas intake pipe 4. The PECVD device further includes a controller 8 (as shown in FIG. 10) electrically connected to a radio frequency power supply 81, the vacuum valve motor 121 (which is used to control the opening and the closing of the vacuum valve), the intake valve 43 and the drive mechanism 131 (i.e. the drive motor or the pneumatic motor). The combined operation between the PECVD device, a feeding mechanism (for automatic feeding the work piece holder), a removing mechanism (for automatic removing the work piece holder) and other devices can be realized via the controller, so as to form an automatic PECVD production line.

In the present embodiment, each vacuum chamber may also use only one plasma emitter.

### Second Embodiment

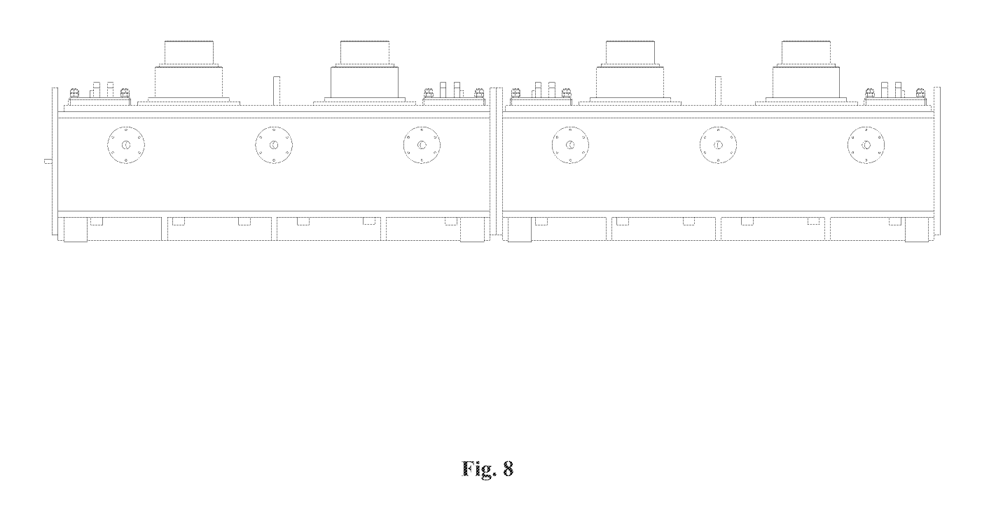

As shown in FIG. 8, in practical application of the flat-plate type PECVD device according to the present application, two or more vacuum cavities (the structure of the vacuum chamber is shown in FIG. 3) may be connected together to realize the deposition of multilayer material film for experimental research or industrial production.

### Third Embodiment

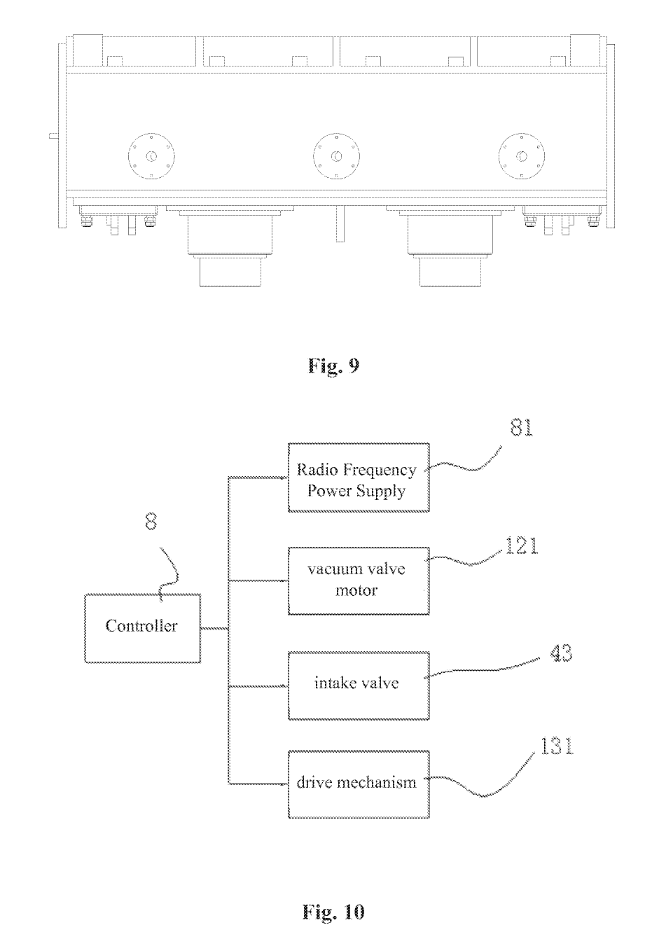

In practical application of the flat-plate type PECVD device according to the present application, the plasma emitter may be mounted below the vacuum chamber to realize the deposition of thin film, as shown in FIG. 9.

### Forth Embodiment

In practical application of the flat-plate type PECVD device according to the present application, especially in laboratory research, in the case of changing the type of the process to gas, the PECVD device according to the present application can also be used to deposit a thin film containing other substances.

In conclusion, the present application employs a radio frequency power supply having a RF frequency ranged from 1 MHz to 300 MHz (the RF frequency is 13.56 MHz in the embodiments), which reduces harm to human body. Meanwhile, since the energy of the plasma is mainly determined by the frequency of the power source, the lower the frequency is, the higher the bombarding energy of the plasma is. Compared to the microwave source (GHz), the plasma generated by the RF frequency (MHz) has a higher energy, thus the deposited product such as a silicon nitride film is denser. The PECVD in direct method generally employs a medium/low frequency power (ranged from 40 KHz to 460 KHz), although the film quality is denser, great damage to the surface of the substrate may be caused by the overly high ion energy. Hence, the present application employs a high power radio frequency power supply and combines an automatic matching network, such that the transmission efficiency of the energy is greatly increased and the radio frequency power may be efficiently transmitted to the plasma. The copper antenna of the present application has a unique butterfly-type shape, and when designing the antenna, the function of directional transmission is emphasized, thus the direction of the plasma is fully controlled by the antenna, thus there is no need to provide an additional magnetic field. Therefore, the present application may efficiently generate a large area of plasma having a high density and being uniform. The plasma and the antenna are separated by the quartz dielectric window employed in the present application, which prevents the antenna from contacting the plasma, thereby avoiding the antenna being eroded, and there is no need to frequently change the quartz tube for protecting the antenna, which reduces many maintenance costs. The present application employs a unique process gas feeding manner, that is the reactive gas is blown to the bottom of the quartz dielectric window from the side face of the lower portion of the electrical dielectric window (i.e. the quartz dielectric window), such that the concentration of the plasma which are adjacent to the electrical dielectric window is greatly decreased and the adhesion of the plasma to the quartz dielectric window is reduced, therefore, the situation that the plasma are gathered and fallen onto the surface of the sample after a long time operation is not easy to happen, which improves the cleanliness of the cell piece (i.e. the work piece). Meanwhile, in design, the even distribution of the gas inlets is emphasized and blind spots of gas distribution are eliminated, such that the gas in the reactive surface of the substrate is more even. The combined operation between the PECVD device in the present application, the feeding mechanism (for automatic feeding the work piece holder), the removing mechanism (for automatic removing the work piece holder) and other devices can be realized via the controller, such that an automatic production line is formed.

In short, the present application has a radio frequency power supply which is stable, safe and has a moderate energy, a copper antenna which controls the plasma, and a unique process gas feeding manner, thus work piece deposited by the present application, such as a silicon nitride film or a silicon oxide film, may have excellent performances, for example, uniformity, compactness and pollution-free.

The above embodiments are only used to illustrate the technical solutions of the present application, and are not intended to limit the present application. Although the present application is illustrated in detail with reference to the above-described embodiments, it is understandable that, for the person skilled in the art, modifications may be made to the technical solutions in the above-described embodiments, or equivalent replacements may be made to several technical features. However, the essence of the corresponding technical solutions will not depart from the sprit and scope of technical solutions of embodiments of the present application due to these modifications and equivalent replacements.

1. A flat-plate type PECVD device, comprising a vacuum chamber for accommodating a work piece and a plasma emitter provided above the vacuum chamber, wherein:
the plasma emitter comprises an emitting box fixed to the vacuum chamber, and a radio frequency impedance matching device provided above the emitting box;
a dielectric window is connected to a bottom portion of the emitting box, and an antenna body connected to the radio frequency impedance matching device is fixedly provided above the emitting box;
the antenna body comprises an antenna placed in the emitting box, and a connecting terminal for connecting the antenna and the radio frequency impedance matching device;
a radio frequency power supply is externally connected to the radio frequency impedance matching device; and
a process gas intake pipe is fixedly provided on the vacuum chamber, and a mounting groove corresponding to the emitting box is provided above the vacuum chamber.

2. The flat-plate type PECVD device according to claim 1, further comprising a work piece holder for holding the work piece, wherein:
the vacuum chamber is of a cuboid shape;
two opposite end faces of the vacuum chamber are respectively provided with an inlet slot and an outlet slot for the work piece; and
a vacuum valve is provided at a side face of the vacuum chamber.

3. The flat-plate type PECVD device according to the claim 2, wherein a support roller for supporting the work piece holder is provided in the vacuum chamber.

4. The flat-plate type PECVD device according to the claim 3, wherein the process gas intake pipe is located below the dielectric window;
the dielectric window is a quartz dielectric window; and
the antenna comprises two butterfly-type copper antennas.

5. The flat-plate type PECVD device according to claim 4, further comprising:
a mounting box for accommodating the radio frequency impedance matching device;
wherein, the connecting terminal is a porcelain through terminal, and a frequency of the radio frequency power supply is ranged from 1 MHz to 300 MHz.

6. The flat-plate type PECVD device according to claim 5, wherein the support roller is a sealed driving wheel fixedly provided on a side wall of the vacuum chamber;
each of two opposite side walls of the vacuum chamber is provided with two to six sealed driving wheels; and
an end of each of the sealed driving wheels extends to an outside of the vacuum chamber and is drivably connected to a drive mechanism.

7. The flat-plate type PECVD device according to claim 5, wherein a sealing baffle is provided outside both the inlet slot and the outlet slot;
the process gas intake pipe is a frame-shaped pipe connected with one intake branch pipe; and
several gas outlet holes, gas outlet directions of which are parallel to a lower end face of the quartz dielectric window, are evenly provided at an outer side of the frame-shaped pipe.

8. The flat-plate type PECVD device according to claim 5, wherein the vacuum chamber is provided, at both an inlet side and an outlet side of the work piece holder, with connecting holes for realizing sealing connection; and
there are more than two vacuum chambers.

9. The flat-plate type PECVD device according to claim 5, wherein the vacuum valve is provided with a vacuum valve motor;
an intake valve is further provided at an inlet end of the process gas intake pipe; and
the PECVD device further comprises a controller electrically connected to the radio frequency power supply, the vacuum valve motor, the intake valve and the drive mechanism.

10. The flat-plate type PECVD device according to claim 6, wherein there are two plasma emitters, two radio frequency impedance matching devices, and two mounting grooves.

11. The flat-plate type PECVD device according to claim 7, wherein there are two plasma emitters, two radio frequency impedance matching devices, and two mounting grooves.

12. The flat-plate type PECVD device according to claim 8, wherein there are two plasma emitters, two radio frequency impedance matching devices, and two mounting grooves.

13. The flat-plate type PECVD device according to claim 9, wherein there are two plasma emitters, two radio frequency impedance matching devices, and two mounting grooves.
